(19) United States
(12) Patent Application Publication
(10) Pub. No.: US 2024/0010806 A1
(43) Pub. Date: Jan. 11, 2024

(54) RESIN SHEET, CONTAINER, CARRIER TAPE, AND ELECTRONIC COMPONENT PACKAGING

(71) Applicant: Denka Company Limited, Chuo-ku, Tokyo (JP)

(72) Inventors: Takeshi SAITO, Chuo-ku, Tokyo (JP); Ryosuke YANAKA, Chuo-ku, Tokyo (JP)

(73) Assignee: Denka Company Limited, Chuo-ku, Tokyo (JP)

(21) Appl. No.: 18/043,979

(22) PCT Filed: Jun. 7, 2021
(86) PCT No.: PCT/JP2021/021608

§ 371 Date: Mar. 3, 2023

(30) Foreign Application Priority Data
Sep. 9, 2020 (JP) 2020-151113

(51) Int. Cl. C08J 7/044; B65D 1/40; C09D 183/04; B65D 73/02

(52) U.S. Cl. CPC C08J 7/044; B65D 1/40; C09D 183/04; B65D 73/02; B65D 2501/24

(57) ABSTRACT

A resin sheet for molding includes a base material sheet, and a surface layer provided on at least one surface of the base material sheet and including silicone, wherein the silicone content in the surface layer is 0.3 to 4.0 g/m², and wherein the base material sheet is formed of a resin composition including 29 to 65 parts by mass of a Styrene-conjugated diene block copolymer (A), 25 to 60 parts by mass of a polystyrene resin (B), and 8 to 20 parts by mass of a high-impact polystyrene resin (C) (provided that a total amount of the component (A), the component (B), and the component (C) is 100 parts by mass). A carrier tape 100 is a molded body 16 of the resin sheet, wherein an accommodation portion 20 capable of accommodating an article is provided.

### TECHNICAL FIELD

The present invention relates to a resin sheet, a container, a carrier tape, and an electronic component packaging body.

### BACKGROUND ART

Vacuum-molded trays, embossed carrier tapes, and the like obtained by heat-molding a resin sheet including a thermoplastic resin are used as packaging containers for intermediate products of industrial products such as electronic instruments and automobiles. When embossed carrier tapes are produced, normally, a slit product (slit raw material) obtained by slit-processing a raw material sheet into a predetermined width is supplied to a molding machine, and pockets or the like are continuously provided. In this case, a slit raw material wound in a reel shape is attached to the molding machine.

Generally, regarding winding of a resin sheet and production of reel-shaped articles, adjustments and devices are made to improve the winding (For example, refer to the following Patent Literature 1).

### CITATION LIST

### Patent Literature

[Patent Literature 1] Japanese Unexamined Patent Publication No. H8-53242

### SUMMARY OF INVENTION

### Technical Problem

However, if adhesiveness of a resin sheet is excessively low, it is difficult to sufficiently curb winding deviation or the like, in a case of a resin sheet used for producing an embossed carrier tape, if winding deviation occurs in a slit raw material wound in a reel shape or deviation occurs in a side edge portion of a slit raw material due to contact or the like with a shaft when the slit raw material is attached, a defect such as deviation of a molding position of a pocket is likely to occur.

On the other hand, when an embossed carrier tape is produced, a pocket may be provided by deep-drawing molding depending on the shape of a component to be packaged. In such a case, there is a need for a resin sheet to be able to be molded into a predetermined shape with generation of holes or the like being curbed. However, a required level of moldability is becoming higher with the increase in size of components for in-vehicle use and the like. Moreover, a provided pocket is required to have a sufficient strength so that it is unlikely to be crushed even in a state of being wound in a reel.

An object of the present invention is to provide a resin sheet in which significant deviation is unlikely to occur even in a case of being used as a slit raw material, which has moldability allowing favorable molding even in a case of performing deep-drawing molding, and with which a molded body having a sufficient strength can be obtained, and a container, a carrier tape, and an electronic component packaging body which are obtained using the resin sheet.

### Solution to Problem

In order to resolve the foregoing problems, according to an aspect of the present invention, there is provided a resin sheet for molding including a base material sheet, and a surface layer provided on at least one surface of the base material sheet and including silicone, wherein the silicone content in the surface layer is 0.3 to 4.0 g/m², and wherein the base material sheet is formed of a resin composition including 29 to 65 parts by mass of a Styrene-conjugated diene block copolymer (A), 25 to 60 parts by mass of a polystyrene resin (B), and 8 to 20 parts by mass of a high-impact polystyrene resin (C) (provided that a total amount of the component (A), the component (B), and the component (C) is 100 parts by mass).

The foregoing resin sheet can have characteristics in which significant deviation is unlikely to occur even in a case of being used as a slit raw material, in other words, sufficient shape stability of a slit raw material. In addition, the foregoing resin sheet has moldability allowing favorable molding even in a case of performing deep-drawing molding whereby a molded body having a sufficient strength can be obtained.

The surface layer can include at least one kind of silicone oil selected from the group consisting of dimethylsilicone oil, methylphenyl silicone oil, methylhydrogen silicone oil, and modified silicone oil.

The surface layer can include modified silicone oil having at least one kind of group selected from the group consisting of a hydroxyl group, a phenyl group, and a carboxyl group.

The surface layer can further include a conductive material.

According to another aspect of the present invention, there is provided a method for manufacturing the foregoing resin sheet including a step of forming the surface layer by coating at least one surface of the base material sheet with a coating liquid including the silicone and drying the coated surface such that an adhesion amount of the dried silicone becomes 0.3 to 4.0 g/m².

According to another aspect of the present invention, there is provided a container that is a molded body of the foregoing resin sheet.

The container may have a part molded into a recessed shape having a bottom wall portion and side wall portions standing from a circumferential edge of the bottom wall portion, and a drawing ratio DR of this part calculated by the following Expression (1) may be 3.5 or larger.

DR=IA/OA (1)

[in Expression (1), IA indicates a total area of inner side surfaces of the bottom wall portion and the side wall portions, and OA indicates an opening area of the recessed shape]

According to another aspect of the present invention, there is provided a carrier tape that is a molded body of the foregoing resin sheet, wherein an accommodation portion capable of accommodating an article is provided.

The accommodation portion may be provided in a recessed shape having a bottom wall portion and side wall portions standing from a circumferential edge of the bottom wall portion, and a drawing ratio DR of this accommodation portion calculated by the following Expression (2) may be 3.5 or larger.

DR=IA/OA (2)

[in Expression (2), IA indicates a total area of inner side surfaces of the bottom wall portion and the side wall portions, and OA indicates an opening area of the recessed shape]

According to another aspect of the present invention, there is provided an electronic component packaging body including the carrier tape, an electronic component accommodated in the accommodation portion of the carrier tape, and a cover film adhered to the carrier tape as a lid material.

### Advantageous Effects of Invention

According to the present invention, it is possible to provide a resin sheet in which significant deviation is unlikely to occur even in a case of being used as a slit raw material, which has moldability allowing favorable molding even in a case of performing deep-drawing molding, and with which a molded body having a sufficient strength can be obtained, and a container, a carrier tape, and an electronic component packaging body which are obtained using the resin sheet.

### BRIEF DESCRIPTION OF DRAWINGS

FIG. 1 is a schematic cross-sectional view illustrating an embodiment of a resin sheet.

FIG. 2 is an explanatory view of accommodation portions of a carrier tape.

FIG. 3 is another explanatory view of the accommodation portion of the carrier tape.

FIG. 4 is a partially-cut perspective view illustrating an embodiment of a carrier tape.

FIG. 5 is a partially-cut perspective view illustrating an embodiment of an electronic component packaging body.

FIG. 6 is a view illustrating a method for evaluating shape stability of a slit raw material.

FIG. 7 is a view illustrating a judgment criterion for evaluating moldability.

### DESCRIPTION OF EMBODIMENT

Hereinafter, a suitable embodiment of the present invention will be described in detail.

[Resin Sheet]

A resin sheet of the present embodiment is a resin sheet for molding and includes a base material sheet and a surface layer provided on at least one surface of the base material sheet.

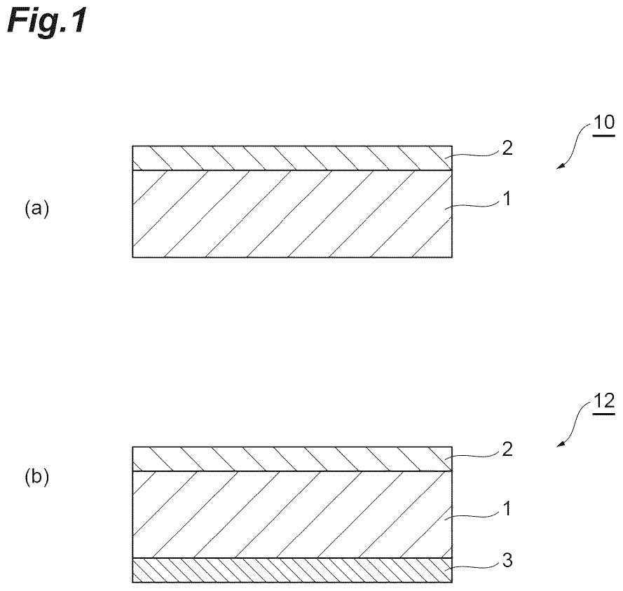

FIG. 1 is a schematic cross-sectional view illustrating an embodiment of a resin sheet of the present embodiment. A resin sheet 10 illustrated in FIG. 1(a) includes a base material sheet 1, and a surface layer 2 provided on one surface of the base material sheet 1. In addition, a resin sheet 12 illustrated in FIG. 1(b) includes the base material sheet 1, the surface layer 2 laminated on one surface of the base material sheet, and a second surface layer 3 laminated on the other surface of the base material sheet. The surface layer 2 and the second surface layer 3 may be layers having the same compositions or may be layers having different compositions.

<Base Material Sheet>

The base material sheet can be formed of a resin composition. The resin composition can include a Styrene-conjugated diene block copolymer (A), a polystyrene resin (B), and a high-impact polystyrene resin (C).

Regarding the Styrene-conjugated diene block copolymer (A), it is possible to use a polymer containing a polymer block having styrene-based monomers as a main constituent and a polymer block having conjugated diene monomers as a main constituent in the structure thereof.

Examples of styrene-based monomers include styrene, o-methylstyrene, p-methylstyrene, p-tert-butylstyrene, 1,3-dimethylstyrene, α-methylstyrene, vinylnaphthalene, vinylanthracene, and 1,1-diphenylethylene. Styrene-based monomers have styrene as a main constituent and can include one or more kinds of the foregoing components other than styrene as minor components.

Conjugated diene monomers need only be compounds having conjugated double bonding in the structure, and examples thereof include 1,3-butadiene (butadiene), 2-methyl-1,3-butadiene (isoprene), 2,3-dimethyl-1,3-butadiene, 1,3-pentadiene, 1,3-hexadiene, and 2-methylpentadiene. Among these, butadiene or isoprene is preferably used. Regarding conjugated diene monomers, one kind can be used alone or two or more kinds can be used in combination.

A polymer block having styrene-based monomers as a main constituent may be a polymer block constituted of only a structure derived from styrene-based monomers or may be a polymer block containing 50 mass % or more of a structure derived from styrene-based monomers.

A polymer block having conjugated diene monomers as a main constituent may be a polymer block constituted of only a structure derived from conjugated diene monomers or may be a polymer block containing 50 mass % or more of a structure derived from conjugated diene monomers.

From a viewpoint of mechanical characteristics of the base material sheet, the conjugated diene content in the Styrene-conjugated diene block copolymer (A) can be set to 10 to 25 mass % based on the mass of the component (A). Here, the conjugated diene content denotes the ratio of the mass of the structure derived from conjugated diene monomers to the total amount of copolymer.

Regarding the Styrene-conjugated diene block copolymer (A), one kind can be used alone or two or more kinds can be used in combination.

For example, when conjugated diene is butadiene, the Styrene-conjugated diene block copolymer (A) may be a binary copolymer of styrene-butadiene (SB), may be a ternary copolymer (SBS) of styrene-butadiene-styrene (SBS), or may be a resin constituted of a plurality of blocks including three or more styrene blocks and two or more butadiene blocks.

The Styrene-conjugated diene block copolymer (A) may have a so-called tapered block structure in which the composition ratio of styrene and butadiene between the blocks continuously changes. In addition, a commercially available Styrene-conjugated diene block copolymer (A) can be used as it is.

In the Styrene-conjugated diene block copolymer (A), from a viewpoint of moldability in deep-drawing molding, the peak molecular weight measured by means of GPC of the polymer block of styrene-based monomers in the component thereof (which may hereinafter be referred to as “a styrene block”) may be within a range of 30,000 to 120,000, and the half-value width of the molecular weight distribution curve of the styrene block may be within a range of 0.8 to 1.25 and is more preferably within a range of 1.05 to 1.25. The molecular weight distribution curve of the styrene block of the component (A) can be obtained by the following method.

First, the component (A) is subjected to oxidative decomposition with chloroform using osmium tetroxide as a catalyst in conformity with the method disclosed in I. M. KOLTHOFF, et al., J. Polym. Sci., 1, 429 (1946). The styrene block obtained in this manner is dissolved in a tetrahydrofuran solvent, and a molecular weight curve is obtained by a GPC method. Further, the peak molecular weight can be obtained by styrene conversion using standard polystyrene (monodispersed) from this molecular weight curve. Measurement by the GPC method at this time is based on an ordinary method, and main measurement conditions are as follows.
Column temperature: 40° C.
Detection method: differential refractive method
Mobile phase: tetrahydrofuran
Sample concentration: 2 mass %
Calibration curve: made based on standard polystyrene
(monodispersed)

The half-value width of the molecular weight distribution curve of the styrene block can be obtained using the molecular weight distribution curve of the styrene block obtained as described above. Specifically, the molecular weight is logarithmically marked while setting a range of 1,000 to 1,000,000 in the horizontal axis to 15 cm, and the concentration (mass ratio) is marked with an arbitrary height in the vertical axis. The width of the 50% peak of the height of the peak top in the horizontal axis is regarded as the half-value width. In this case, it is required that the height of the peak top be perpendicular to the horizontal axis and the width of the 50% peak of the height be horizontal with respect to the horizontal axis.

The peak molecular weight of the styrene block and the half-value width of the molecular weight distribution curve can be adjusted by a method for adjusting the time at which an initiator is added, or the like, for example, during polymerization of the styrene block part of the component (A).

In the Styrene-conjugated diene block copolymer (A), from a viewpoint of sheet-film formability, a weight average molecular weight (Mw) may be 80,000 to 220,000. In this specification, the weight average molecular weight (Mw) can be obtained from the molecular weight distribution curve through standard polystyrene conversion obtained by an ordinary method using GPC.

The polystyrene resin (B) is a resin which is generally referred to as GPPS, and styrene is a main constituent or monomers. However, as minor components, it may contain one or more kinds of aromatic vinyl compounds such as o-methylstyrene, p-methylstyrene, p-tert-butylstyrene, 1,3-dimethylstyrene, α-methylstyrene, vinylnaphthalene, vinylanthracene, and 1,1-diphenylethylene. Regarding the polystyrene resin (B), a commercially available resin can also be used.

The weight average molecular weight (Mw) of the polystyrene resin (B) may be 200,000 to 400,000.

The high-impact polystyrene resin (C) is a resin generally referred to as HIPS, and a polystyrene resin-containing graft rubber in a fine particle state in which styrene-based monomers are grafted can be used. Regarding styrene-based monomers, monomers similar to those in the component (A) can be used. The graft rubber is obtained by forming graft branches through graft copolymerization of styrene-based monomers in a rubber component. Regarding a rubber component in the graft rubber, for example, diene-based rubber having 1,3-butadiene (butadiene), 2-methyl-1,3-butadiene (isoprene), 2,3-dimethyl-1,3-butadiene, 1,3-pentadiene, 1,3-hexadiene, 2-methylpentadiene, or the like as monomers is used. Regarding the graft rubber, a thermoplastic elastomer of a Styrene-conjugated diene block copolymer having a diene component of 50 mass % or more can also be used. From a viewpoint of sheet-film formability, the graft rubber is preferably polybutadiene or a styrene-butadiene block copolymer.

In the graft rubber in the component (C), from a viewpoint of transparency, the particle size may be 2.0 μm to 3.0 μm or may be 2.3 μm to 2.7 μm. The particle size of the graft rubber denotes the average particle size of the graft rubber measured by a laser diffraction-type particle analyzer.

From a viewpoint of sheet-film formability and transparency, in the base material sheet, it is preferable that the rubber content of the graft rubber in the base material sheet when it is regarded that there is 100 mass % of the base material sheet be 0.75 to 1.90 mass %, in this case, the rubber content in the base material sheet can be set within the foregoing range by adjusting the rubber content of the graft rubber in the component (C) and the blending ratio of the component (C) in the base material sheet. The graft rubber content in the component (C) can be calculated from a value of the mass of the insoluble matter collected through centrifugal separation when being dissolved in a mixed solvent of MEK and acetone with the mass ratio of 50/50.

In the high-impact polystyrene resin (C), the weight average molecular weight (Mw) may be 150,000 to 210,000.

From a viewpoint of achieving both moldability and strength, the contents of the component (A), the component (B), and the component (C) in the resin composition can be respectively set to 29 to 65 parts by mass, 25 to 60 parts by mass, and 8 to 20 parts by mass when the total amount of the component (A), the component (B), and the component (C) is 100 parts by mass.

From a viewpoint of sheet-film formability, the total content of the component (A), the component (B), and the component (C) in the resin composition may be 80 mass % or more, may be 90 mass % or more, or may be 100 mass % based on the total amount of the resin composition.

The resin composition may contain a conductive material, an antioxidant, an anti-blocking agent, or the like. When the resin composition contains a conductive material, a formed base material sheet can have conductivity or antistatic properties.

A general method can be used as a method for manufacturing a base material sheet using the resin composition described above. For example, the components (A) to (C) are mixed in at predetermined proportions, are mixed using a mixer such as a tumbler, and are kneaded using an extruder, thereby obtaining a pelletized compound. This pelletized compound is extrusion-molded using an extruder (465 mm) and a T-die, and a base material sheet can thereby be manufactured. In addition, a so-called “edge” part or the like generated in this extrusion step may be crushed and returned as a raw material for a base material sheet within a range not significantly affecting the strength of a base material sheet or a molded article after molding processing.

The thickness of the base material sheet can be suitably set in accordance with the purpose thereof. For example, it may be 50 μm to 3 mm, may be 100 μm to 1 mm, or may be 150 to 600 μm.

<Surface Layer>

From a viewpoint of moldability, the surface layer can include silicone. The surface layer can include at least one kind of silicone oil selected from the group consisting of dimethylsilicone oil, methylphenyl silicone oil, methylhydrogen silicone oil, and modified silicone oil as silicone.

From a viewpoint of adhesiveness with respect to a base material sheet and shape stability of a slit raw material, the surface layer can include modified silicone oil having at least one kind of group selected from the group consisting of a hydroxyl group, a phenol group, and a carboxyl group.

From a viewpoint of moldability and shape stability of a slit raw material, the silicone content in the surface layer can be set to 0.3 to 4.0 g/m² or can be set to 0.5 to 2.5 g/m².

The surface layer can further include a conductive material. In this case, the surface layer can also function as a conductive layer. Examples of a conductive material include carbon black, graphite, carbon nanotubes (CNT), black lead, and Ketjen black. When carbon nanotubes are used, deterioration in transparency of a formed surface layer can be curbed. For example, carbon nanotubes having diameters of ϕ3 to 15 nm and lengths of 0.5 to 3 μm can be used.

Regarding a conductive material, one kind can be used alone or two or more kinds can be used in combination.

From a viewpoint of antistatic properties and transparency, the content of the conductive material in the surface layer can be set to 0.01 to 1.0 g/m² and can be set to 0.05 to 0.5 g/m².

In the surface layer including a conductive material, it is preferable that the surface resistivity be 10⁴ to 10¹⁰Ω/□. When the surface resistivity is within this range, the resin sheet can be favorably used for producing a molded body for an electronic component package, and therefore it is easy to prevent destruction of electronic components due to static electricity or destruction of electronic components due to electricity flowing in from outside.

<Second Surface Layer>

As in the resin sheet 12 illustrated in FIG. 1(b), when the second surface layer 3 is provided, the second surface layer 3 may contain the conductive material described above. In this case, a second surface layer can function as a conductive layer.

From a viewpoint of antistatic properties and transparency, the content of the conductive material in the second surface layer can be set to 0.05 to 3.0 g/m² or can be set to 0.1 to 1.5 g/m². In addition, in the second surface layer, it is preferable that the surface resistivity be 10⁴ to 10¹⁰Ω/□.

The resin sheet of the present embodiment may be an unprocessed raw material sheet or may be a slit product (slit raw material) or the like which has been subjected to predetermined processing.

The resin sheet of the present embodiment can be molded into a shape according to the purpose by a known thermal molding method such as a vacuum molding method, a pressure molding method, and a press molding method. In a press molding method, compared to a vacuum molding method and a pressure molding method, a bottomed cylinder and a rectangular cylinder shape can be sharply molded, but perforation is likely to occur. Since the resin sheet of the present embodiment has excellent moldability, even in a case in which molding is performed by a press molding method (particularly, deep-drawing molding), it can be molded into a favorable shape while perforation is curbed. For this reason, the resin sheet of the present embodiment is also useful as a resin sheet for press molding (particularly, for deep-drawing molding).

The resin sheet of the present embodiment can be used as a material of a packaging container for active components such as ICs, components including an IC, passive components such as capacitors and connectors, and mechanism components and can be favorably used for vacuum-molded trays, magazines, carrier tapes provided with embossing (embossed carrier tapes), and the like.

According to the resin sheet of the present embodiment, it is possible to have characteristics in which significant deviation is unlikely to occur even in a case of being used as a slit raw material, in other words, sufficient shape stability of a slit raw material. In addition, the resin sheet of the present embodiment has moldability allowing favorable molding even in a case of performing deep-drawing molding whereby a molded body having a sufficient strength can be obtained.

[Method for Manufacturing Resin Sheet]

The resin sheet according to the present embodiment can be manufactured by a method including a step of forming the surface layer by coating at least one surface of the base material sheet described above with a coating liquid including each of the components described above and drying the coated surface.

A coating liquid can be prepared by mixing in the components described above using a dissolver or the like. The coating liquid may contain a dispersion medium such as water, ethyl acetate, or toluene, or a dispersant such as sulfonic acid dispersant having an aromatic group in the molecules. From a viewpoint of curbing discoloration and deterioration of the base material sheet, the coating liquid is preferably aqueous. In this case, each of the components can be mixed in a form of an emulsion or an aqueous dispersion.

A known method can be used as a means for coating with a coating liquid, and examples thereof include a gravure coater, a gravure roll, and a bar coater.

The silicone content in the coating liquid and the coating amount of the coating liquid can be adjusted such that the adhesion amount of the dried silicone is within the range of the content described above. Similarly, even when the coating liquid includes a conductive material, they can be adjusted such that the adhesion amount of the dried conductive material is within the range of the content described above.

When the surface layer includes a conductive material, the coating liquid can contain an acrylic copolymer. For example, an acrylic copolymer can be mixed in a form of an emulsion or an aqueous dispersion. The particle size of the acrylic copolymer (here, the average particle size is a value of a median diameter) may be 80 nm to 350 nm or may be 100 to 250 nm. In addition, from a viewpoint of appropriately maintaining the conductivity of the surface layer, it is preferable that a glass-transition temperature Tg of the acrylic copolymer be 25° C. to 80° C.

When the resin sheet has the second surface layer, the second surface layer can be formed in a manner similar to that of the surface layer.

[Container, Carrier Tape, and Electronic Component Packaging Body]

A container of the present embodiment is a molded body of the foregoing resin sheet according to the present embodiment. A container can be obtained by molding the resin sheet according to the present embodiment into a shape according to the purpose.

A known thermal molding method such as a vacuum molding method, a pressure molding method, or a press molding method can be used as the molding method. Particularly, a pocket shape of the container can be sharply molded while occurrence of perforation is curbed by molding (particularly, deep-drawing molding) the resin sheet of the present embodiment by a press molding method.

Examples of a molding temperature include 80° C. to 500° C.

The container may have a part molded into a recessed shape having a bottom wall portion and side wall portions standing from a circumferential edge of the bottom wall portion, and a drawing ratio DR of this part calculated by the following Expression (1) may be 3.5 or larger.

DR=IA/OA (1)

[in Expression (1), IA indicates a total area of inner side surfaces of the bottom wall portion and the side wall portions, and OA indicates an opening area of the recessed shape]

In the container of the present embodiment, since the resin sheet according to the present embodiment has excellent moldability, the drawing ratio DR of the part molded into a recessed shape may be 4.0 or larger or may be 5.0 or larger.

A carrier tape of the present embodiment is a molded body of the foregoing resin sheet according to the present embodiment and is provided with accommodation portions capable of accommodating articles.

The accommodation portions may be provided in a recessed shape having a bottom wall portion and side wall portions standing from a circumferential edge of the bottom wall portion, and a drawing ratio DR of these accommodation portions calculated by the following Expression (2) may be 3.5 or larger, may be 4.0 or larger, or may be 5.0 or larger.

DR=IA/OA (2)

[in Expression (1), IA indicates a total area of inner side surfaces of the bottom wall portion and the side wall portions, and OA indicates an opening area of the recessed shape]

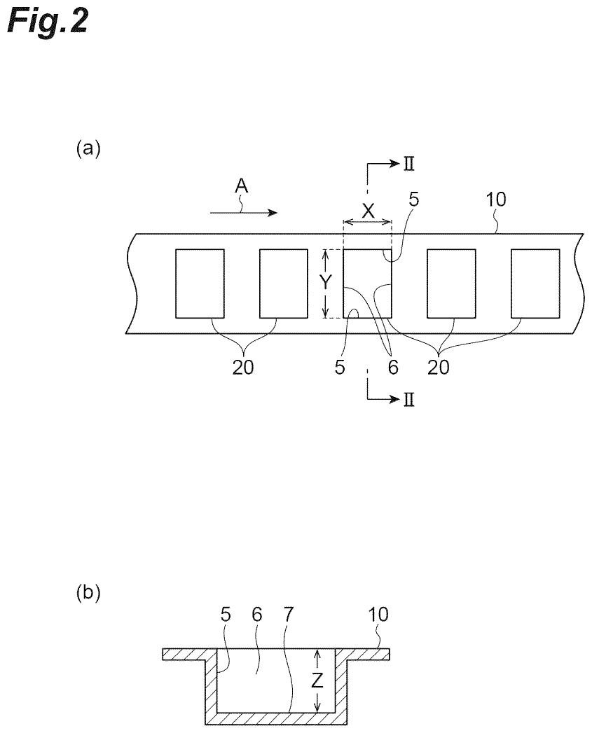

FIG. 2 is an explanatory view of the accommodation portions of the carrier tape. FIG. 2(a) is a top view, and FIG. 2(b) is a cross-sectional view along line II-II indicated in FIG. 2(a). The carrier tape illustrated in FIG. 2 has accommodation portions (pockets) 20 which are provided by molding the resin sheet 10. A in FIG. 2(a) indicates a traveling direction of the carrier tape (molded body).

Each of the accommodation portions 20 has a recessed shape having a bottom wall portion 7 and side wall portions 5 and 6 standing from the circumferential edge of the bottom wall portion 7, and corners formed by the inner side surface of the bottom wall portion 7, and the inner side surfaces of the side wall portions 5 and the inner side surfaces of the side wall portions 6 substantially form right angles. In addition, the opening portions on the tape surface have a square shape or a rectangular shape. The drawing ratio DR of such accommodation portions can be calculated by the following Expression.

DR=[(SA1)+(SA2)+(BA)]/OA

Here, SA1 indicates the total area of the inner side surfaces of two side walls parallel to the direction A and is calculated from 2×X×Z. X indicates the side lengths of the side wall portions in the direction A, and Z indicates the depths of the accommodation portions. SA2 indicates the total area of the inner side surfaces of two side walls orthogonal to the direction A and is calculated from 2×Y×Z. Y indicates the side lengths of the side wall portions in a direction orthogonal to the direction A, and Z indicates the depths of the accommodation portions. BA indicates the area of the inner side surface of the bottom wall portion and is calculated from X×Y. OA indicates the opening area and is calculated from X×Y.

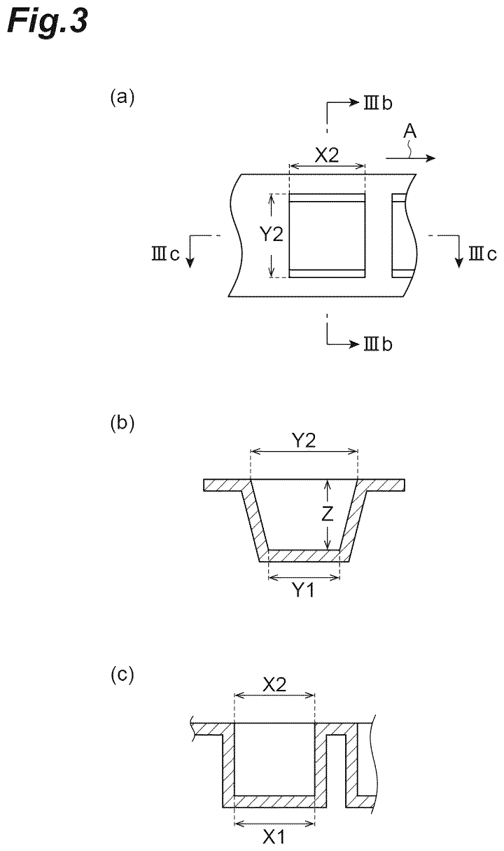

FIG. 3 is also an explanatory view of the accommodation portion.

FIG. 3(a) is a top view, FIG. 3(b) is a cross-sectional view along line IIIb-IIIb indicated in FIG. 3(a), and FIG. 3(c) is a cross-sectional view along line IIIc-IIIc indicated in FIG. 3(a). A in FIG. 3(a) indicates the traveling direction of the carrier tape (molded body). Here, corners formed by the inner side surface of the bottom wall portion and the inner side surfaces of the side wall portions parallel to the direction A substantially form right angles. In addition, the opening portions on the tape surface have a square shape or a rectangular shape.

The drawing ratio DR of such accommodation portions can be calculated by the following Expression.

DR=[(SA1)+(SA2)−(BA)]/OA

Here, SA1 indicates the total area of the inner side surfaces of two side walls parallel to the direction A and is calculated from 2×X1×Z′. X1 indicates the side lengths of the side wall portions in the direction A, and Z′ indicates the distance (gap) between two sides of the side wall portions parallel to the direction A. SA2 indicates the total area of the inner side surfaces of two side walls orthogonal to the direction A and is calculated from 2×[{(Y1+Y2)/2}×Z]. Y1 and Y2 respectively indicate the side lengths of the side wall portions in a direction orthogonal to the direction A, and Z indicates the depths of the accommodation portions. BA indicates the area of the inner side surface of the bottom wall portion and is calculated from X1×Y1. X1 indicates the side length of the bottom wall portion in the direction A, and Y1 indicates the side length of the bottom wall portion in a direction orthogonal to the direction A. OA indicates the opening area and is calculated from X2×Y2. X2 indicates the side lengths of the opening portions in the direction A, Y2 indicates the side lengths of the opening portions in a direction orthogonal to the direction A.

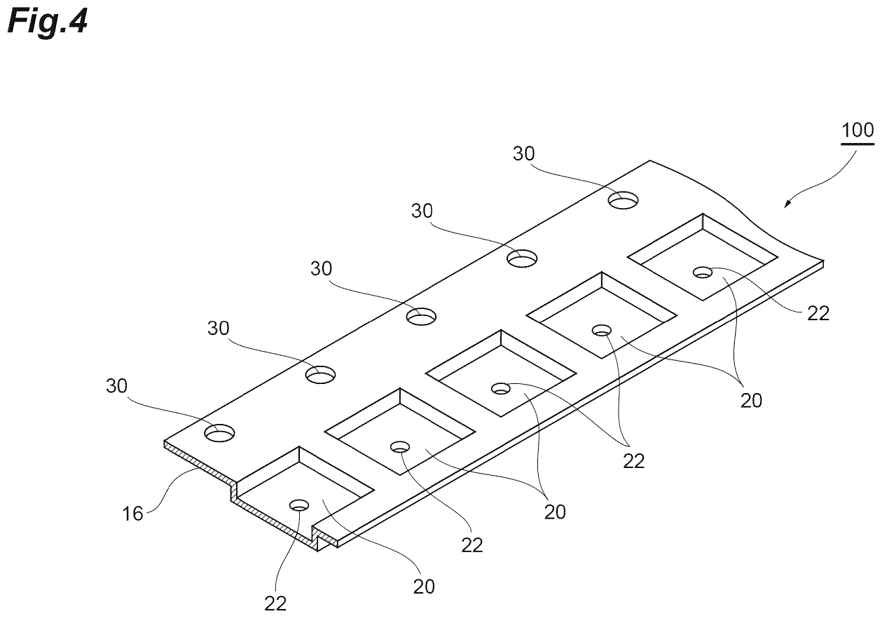

FIG. 4 is a perspective view illustrating an embodiment of a carrier tape. A carrier tape 100 illustrated in FIG. 4 is an embossed carrier tape constituted of a molded body 16 of the resin sheet according to the present embodiment in which accommodation portions 20 are provided by embossing molding. The molded body 16 is provided with sprocket holes 30 which can be used for conveyance in a step of enclosing various kinds of electronic components such as ICs, or the like. Holes 22 may be provided in bottom portions of the accommodation portions 20 for inspection of electronic components.

The carrier tape of the present embodiment can be wound in a reel shape.

The carrier tape of the present embodiment is suitable for a container for packaging electronic components. Examples of electronic components include ICs, light emitting diodes (LEDs), resistors, liquid crystals, capacitors, transistors, piezoelectric element resistors, filters, crystal oscillators, crystal vibrators, diodes, connectors, switches, volumes, relays, and inductors. Electronic components may be intermediate products using the foregoing components or may be final products.

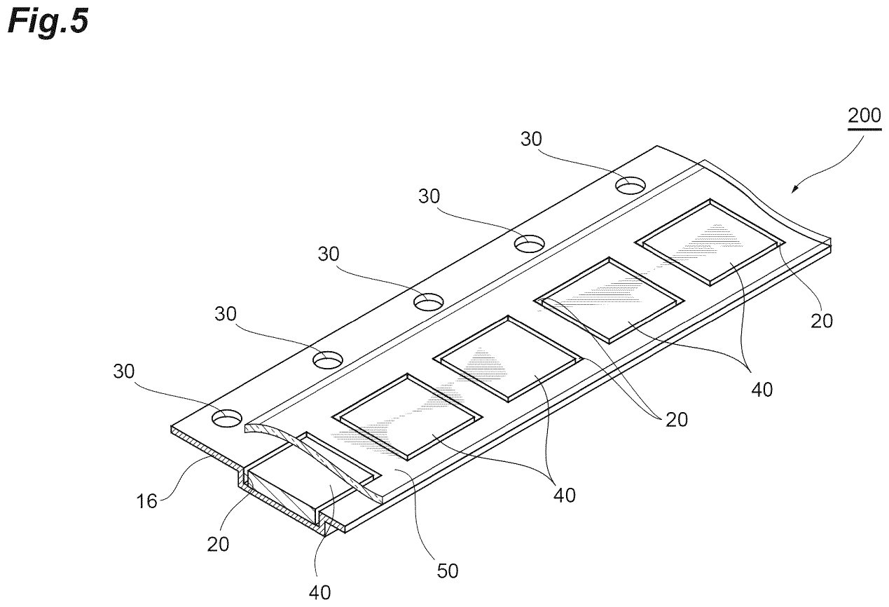

An electronic component packaging body of the present embodiment includes the foregoing carrier tape of the present embodiment, electronic components accommodated in the accommodation portions of the carrier tape, and a cover film adhered to the carrier tape as a lid material. FIG. 5 is a partially-cut perspective view illustrating an embodiment of an electronic component packaging body. An electronic component packaging body 200 illustrated in FIG. 5 includes an embossed carrier tape constituted of the molded body 16 of the resin sheet according to the present embodiment provided with the accommodation portions 20 and the sprocket holes 30, electronic components 40 accommodated in the accommodation portions 20, and a cover film 50 adhered to the embossed carrier tape.

Examples of a cover film include those disclosed in Japanese Patent No. 4630046 and Japanese Patent No. 5894578.

The cover film can be adhered to the upper surface of the embossed carrier tape accommodating the electronic components by heat sealing.

The electronic component packaging body of the present embodiment can be used for storing and conveying electronic components as a carrier tape body wound in a reel shape.

### EXAMPLE

Hereinafter, the present invention will be more specifically described with examples and comparative examples. However, the present invention is not limited to the following examples.

[Production of Resin Sheet]

### Examples 1 to 14 and Comparative Examples 1 to 6

Each of the raw materials shown in Tables 1 to 3 was measured such that it has the composition ratio (mass %) shown in the same tables, and the raw materials were uniformly mixed using a high-speed mixer. Thereafter, they were kneaded using a vent-type twin screw extruder (ϕ45 mm) and were pelletized by a strand cutting method, and a base material sheet forming resin composition was obtained. Using this composite, a base material sheet was produced by means of an extruder (ϕ30 mm) (L/D=28). The thickness of the base material sheet was 0.4 mm.

One surface of the obtained base material sheet was coated with the coating liquid shown in Tables 1 to 3 using a gravure coater and a gravure roll such that the adhesion amount of the dried silicone became the amount shown in the same tables, the coated film was dried at 80° C., and a surface layer was thereby formed.

### Example 15

Each of the raw materials shown in Table 3 was measured such that it has the composition ratio (mass %) shown in the same table, and the raw materials were uniformly mixed using a high-speed mixer. Thereafter, they were kneaded using a vent-type twin screw extruder (ϕ45 mm) and were pelletized by a strand cutting method, and a base material sheet forming resin composition was obtained. Using this composite, a base material sheet was produced by means of an extruder (ϕ30 mm) (L/D=28). The thickness of the base material sheet was 0.4 mm.

One surface of the obtained base material sheet was coated with the coating liquid shown in Table 3 using a gravure coater and a gravure roll such that the adhesion amount of the dried silicone became the amount shown in the same table, the coated film was dried at 80° C., and a surface layer was thereby formed.

Next, the other surface of the base material sheet was coated with the coating liquid shown in Table 3 using a gravure coater and a gravure roll such that the adhesion amount of a dried conductive material became the amount shown in the same table, the coated film was dried at 80° C., and a conductive layer was thereby formed.

### Example 16

Each of the raw materials shown in Table 3 was measured such that it has the composition ratio (mass %) shown in the same table, and the raw materials were uniformly mixed using a high-speed mixer. Thereafter, they were kneaded using a vent-type twin screw extruder (ϕ45 mm) and were pelletized by a strand cutting method, and a base material sheet forming resin composition was obtained. Using this composite, a base material sheet was produced by means of an extruder (ϕ30 mm) (L/D=28). The thickness of the base material sheet was 0.4 mm.

One surface of the obtained base material sheet was coated with the coating liquid shown in Table 3 using a gravure coater and a gravure roll such that the adhesion amount of each of the dried silicone and the dried conductive material became the amount shown in the same table, the coated film was dried at 80° C., and a surface layer was thereby formed.

Details of the raw materials and the coating liquids shown in Tables 1 to 3 are as follows.

(Styrene-Conjugated Diene Block Copolymer)

Styrene-butadiene block copolymer: weight average molecular weight of 150,000, styrene content of 74 mass %, and conjugated diene content of polymer block having butadiene as main constituent of 26 mass %

(Polystyrene Resin)

Polystyrene: weight average molecular weight of 330,000

(High-Impact Polystyrene Resin)

High-impact polystyrene: weight average molecular weight of 180,000, and rubber particle size of 2.2 μm

[Coating Liquid]

(a1)

A coating liquid was adjusted to have a non-volatile component of 5% by mixing in dimethylsilicone oil (brand name: KM-9782, manufactured by SHIN-ETSU CHEMICAL CO., LTD., a silicone emulsion, a non-volatile component of 37%) and water.

(a2)

A coating liquid was adjusted to have a non-volatile component of 5% by mixing in methylphenyl silicone oil (brand name: KF-53, manufactured by SHIN-ETSU CHEMICAL CO., LTD.) and ethyl acetate.

(a3)

A coating liquid was adjusted to have a non-volatile component of 5% by mixing in methylhydrogen silicone oil (brand name: KF-99, manufactured by SHIN-ETSU CHEMICAL CO., LTD.) and ethyl acetate.

(a4)

A coating liquid was adjusted to have a non-volatile component of 5% by mixing in modified silicone oil (containing hydroxyl group) (brand name: KF-9701, manufactured by SHIN-ETSU CHEMICAL CO., LTD.) and ethyl acetate.

(a5)

A coating liquid was adjusted to have a non-volatile component of 5% by mixing in modified silicone oil (containing phenyl group) (brand name: KM-9739, manufactured by SHIN-ETSU CHEMICAL CO., LTD., a silicone emulsion, a non-volatile component of 30%) and water.

(a6)

A coating liquid was adjusted to have a non-volatile component of 5% by mixing in modified silicone oil (containing carboxyl group) (brand name: DOWSIL DK Q2-103-22, manufactured by DOW TORAY CO., LTD., a silicone emulsion, a non-volatile component of 21%) and water.

(b1)

A coating liquid was adjusted by mixing in silicone emulsion (brand name: KM-9782, manufactured by SHIN-ETSU CHEMICAL CO., LTD.), an acrylic copolymer emulsion (brand name: EC242, manufactured by SHIN-NAKAMURA CHEMICAL CO., LTD.), and a carbon nanotube aqueous dispersion (brand name: N7006L, manufactured by KJ SPECIALTY PAPER CO., LTD.) such that the mass ratio after being dried became 50:45:5.

(b2)

A coating liquid was adjusted by mixing in an acrylic copolymer emulsion (brand name: EC242, manufactured by SHIN-NAKAMURA CHEMICAL CO., LTD.) and a carbon nanotube aqueous dispersion (brand name: N7006L, manufactured by KJ SPECIALTY PAPER CO., LTD.) such that the mass ratio after being dried became 95:5.

[Evaluation of Resin Sheet]

Sampling was performed in the extrusion direction of the resin sheet, and evaluation was performed by the method described below. Tables 1 to 3 summarize these results.

(1) Shape Stability

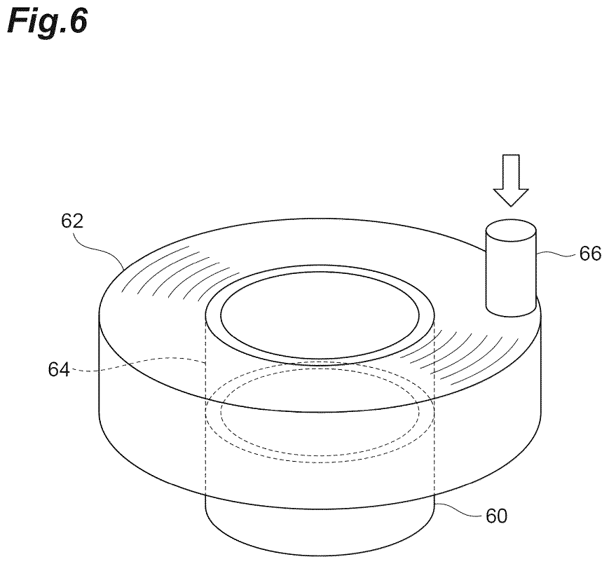

After a raw material in which a resin sheet having a width of 640 mm was wound (400 m) was stored for one month under an environment at 23° C., it was slit to have a width of 24 mm, and a slit raw material wound (200 in) around a paper tube (3 inches) with a winding tension of 1.0 kgf was produced. As illustrated in FIG. 6, a paper tube 60 (3 inches) was placed on a desk, and a weight 66 (1 kg) was placed on an outer circumferential portion of a slit raw material 62 in a slate in which a paper tube part 64 of the slit raw material 62 was placed such that it overlapped this paper tube thereon. The deviation amount in the width direction at this time was measured, and the shape stability was evaluated based on the following judgment criterion.

<Judgment Criterion>

A: Deviation in the width direction was within 2 mm.

B: Deviation in the width direction was 2 mm to smaller than 5 mm.

C: Deviation in the width direction was 5 mm or larger.

(2) Moldability

The resin sheet was molded using a press molding machine under a condition at a heater temperature of 190° C., and a molded body having pockets with the drawing ratio shown in Tables 1 to 3 was produced. The pockets had a recessed shape similar to that illustrated in FIG. 3, and the pocket sizes for respective drawing ratios were as follows.

<3.5 Times of Drawing Ratio>
X1: 8 mm, X2: 8 mm, Y1: 7 mm, Y2: 9 mm, and Z: 7 mm

<4 Times of Drawing Ratio>
X1: 8 mm, X2: 8 mm, Y1: 7 mm, Y2: 10 mm, and Z: 8 mm

<5 Times of Drawing Ratio>
X1: 8 mm, X2: 8 mm, Y1: 7 mm, Y2: 10 mm, and Z: 12.1 mm

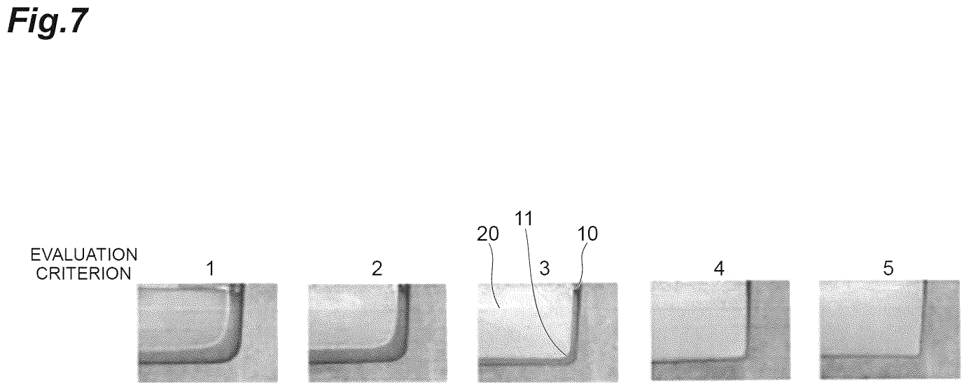

The pockets of the obtained molded body were observed using a microscope, and the sharpness of the corners (circumferential edge of the bottom wall portion) 11 of the pockets were evaluated in five stages in accordance with the evaluation criterion illustrated in FIG. 7. In addition, the pockets of the obtained molded body were visually observed, and the presence or absence of occurrence of perforation was checked. On the basis of these results, the moldability was evaluated based on the following judgment criterion.

<Judgment Criterion>

A: Sharpness was 4 or larger, and there was no perforation.

B: Sharpness was 3 or larger, and there was no perforation.

C: There was perforation, or although there was no perforation but the sharpness was 2 or smaller.

(3) Buckling Strength

Using Strograph (manufactured by TOYO SEIKI SEISAKU-SHO, LTD.), the greatest strength when the bottom wall portion of the pocket was compressed in the depth direction was measured while the opening portion of the pocket of the obtained molded body to face downward, and this was taken as the buckling strength.

TABLE 1

| | | Example 1 | Example 2 | Example 3 | Example 4 | Example 5 | Example 6 | Example 7 |
|---|---|---|---|---|---|---|---|---|
| Surface layer | Coating liquid | a1 | a1 | a1 | a1 | a1 | a1 | a1 |
| | Adhesion amount of | 2.0 | 2.0 | 2.0 | 2.0 | 2.0 | 0.5 | 3.5 |
| | silicone (g/m²) | | | | | | | |
| Base material | Styrene-conjugated | 40 | 29 | 65 | 40 | 30 | 40 | 40 |
| sheet | diene block copolymer | | | | | | | |
| | Polystyrene resin | 45 | 60 | 25 | 52 | 50 | 45 | 45 |
| | High-impact | 15 | 11 | 10 | 8 | 20 | 15 | 15 |
| | polystyrene resin | | | | | | | |
| Drawing ratio of molded body | | 3.5 | 3.5 | 3.5 | 3.5 | 3.5 | 3.5 | 3.5 |
| Evaluation | Shape stability of slit | B | B | B | B | B | A | B |
| | raw material | | | | | | | |
| | Moldability | A | A | A | A | A | A | A |
| | Buckling strength (N) | 26 | 31 | 21 | 28 | 28 | 25 | 28 |

TABLE 2

| | | Example 8 | Example 9 | Example 10 | Example 11 | Example 12 | Example 13 | Example 14 |
|---|---|---|---|---|---|---|---|---|
| Surface layer | Coating liquid | a2 | a3 | a4 | a5 | a6 | a1 | a1 |
| | Adhesion amount of | 2.0 | 2.0 | 2.0 | 2.0 | 2.0 | 2.0 | 2.0 |
| | silicone (g/m²) | | | | | | | |
| Base material | Styrene-conjugated | 40 | 40 | 40 | 40 | 40 | 40 | 40 |
| sheet | diene block copolymer | | | | | | | |
| | Polystyrene resin | 45 | 45 | 45 | 45 | 45 | 45 | 45 |
| | High-impact | 15 | 15 | 15 | 15 | 15 | 15 | 15 |
| | polystyrene resin | | | | | | | |
| Drawing ratio of molded body | | 3.5 | 3.5 | 3.5 | 3.5 | 3.5 | 4.0 | 5.0 |
| Evaluation | Shape stability of slit | B | B | A | A | A | B | B |
| | raw material | | | | | | | |
| | Moldability | A | A | A | A | A | B | B |
| | Buckling strength (N) | 26 | 26 | 26 | 26 | 26 | 24 | 21 |

TABLE 3

| | | | | Comparative | Comparative | Comparative | Comparative | Comparative | Comparative |
|---|---|---|---|---|---|---|---|---|---|
| | | Example 15 | Example 16 | Example 1 | Example 2 | Example 3 | Example 4 | Example 5 | Example 6 |
| Surface | Coating liquid | a1 | b1 | a1 | a1 | a1 | a1 | a1 | a1 |
| layer | Adhesion amount | 2.0 | 1.0 | 2.0 | 2.0 | 2.0 | 2.0 | 0.2 | 5.0 |
| | of silicone (g/m²) | | | | | | | | |
| | Adhesion amount | — | 0.1 | — | — | — | — | — | — |
| | of conductive | | | | | | | | |
| | material (g/m²) | | | | | | | | |
| Base | Styrene- | 40 | 40 | 20 | 70 | 30 | 40 | 40 | 40 |
| material | conjugated diene | | | | | | | | |
| sheet | block copolymer | | | | | | | | |
| | Polystyrene resin | 45 | 45 | 70 | 20 | 45 | 55 | 45 | 45 |
| | High-impact | 15 | 15 | 10 | 10 | 25 | 5 | 15 | 15 |
| | polystyrene resin | | | | | | | | |
| Conductive | Coating liquid | b2 | — | — | — | — | — | — | — |
| layer | Adhesion amount | 1.0 | — | — | — | — | — | — | — |
| | of conductive | | | | | | | | |
| | material (g/m²) | | | | | | | | |
| Drawing ratio of molded body | | 3.5 | 3.5 | 3.5 | 3.5 | 3.5 | 3.5 | 3.5 | 3.5 |
| Evaluation | Shape stability of | B | B | B | B | B | B | A | C |
| | slit raw material | | | | | | | | |
| | Moldability | A | A | C | B | A | C | C | A |
| | Buckling strength | 27 | 26 | 20 | 16 | 18 | 29 | 19 | 29 |
| | (N) | | | | | | | | |

As shown in Tables 1 to 3, in Examples 1 to 16, it was confirmed that the judgment of the shape stability of the slit raw material and the moldability was B or A and the molded body had a buckling strength of 20 N or larger.

### REFERENCE SIGNS LIST

1 Base material sheet
2 Surface layer
3 Second surface layer
5, 6 Side wall portions
7 Bottom wall portion
10, 12 Resin sheet
20 Accommodation portion
22 Hole
30 Sprocket holes
40 Electronic component
50 Cover film
100 Carrier tape
200 Electronic component packaging body

1. A resin sheet for molding comprising:
a base material sheet; and
a surface layer provided on at least one surface of the base material sheet and including silicone,
wherein the silicone content in the surface layer is 0.3 to 4.0 g/m², and
wherein the base material sheet is formed of a resin composition including 29 to 65 parts by mass of a Styrene-conjugated diene block copolymer (A), 25 to 60 parts by mass of a polystyrene resin (B), and 8 to 20 parts by mass of a high-impact polystyrene resin (C) in terms of proportions provided that a total amount of (A), (B), and (C) is 100 parts by mass.

2. The resin sheet according to claim 1,
wherein the surface layer includes at least one kind of silicone oil selected from the group consisting of dimethylsilicone oil, methylphenyl silicone oil, methylhydrogen silicone oil, and modified silicone oil.

3. The resin sheet according to claim 1,
wherein the surface layer includes modified silicone oil having at least one kind of group selected from the group consisting of a hydroxyl group, a phenol group, and a carboxyl group.

4. The resin sheet according to claim 1,
wherein the surface layer further includes a conductive material.

5. A method for manufacturing the resin sheet according to claim 1 comprising:
a step of forming the surface layer by coating at least one surface of the base material sheet with a coating liquid including the silicone and drying the coated surface such that an adhesion amount of the dried silicone becomes 0.3 to 4.0 g/m².

6. A container that is a molded body of the resin sheet according to claim 1.

7. The container according to claim 6,
wherein the container has a part molded into a recessed shape having a bottom wall portion and side wall portions standing from a circumferential edge of the bottom wall portion, and a drawing ratio DR of the part calculated by the following Expression (1) is 3.5 or larger.
DR=IA/OA (1)
[in Expression (1), IA indicates a total area of inner side surfaces of the bottom wall portion and the side wall portions, and OA indicates an opening area of the recessed shape]

8. A carrier tape that is a molded body of the resin sheet according to claim 1,
wherein an accommodation portion capable of accommodating an article is provided.

9. The carrier tape according to claim 8,
wherein the accommodation portion is provided in a recessed shape having a bottom wall portion and side wall portions standing from a circumferential edge of the bottom wall portion, and a drawing ratio DR of the accommodation portion calculated by the following Expression (2) is 3.5 or larger.
DR=IA/OA (2)
[in Expression (2), IA indicates a total area of inner side surfaces of the bottom wall portion and the side wall portions, and OA indicates an opening area of the recessed shape]

10. An electronic component packaging body comprising:
the carrier tape according to claim 8;
an electronic component accommodated in the accommodation portion of the carrier tape; and
a cover film adhered to the carrier tape as a lid material.
